(19) United States
(12) Patent Application Publication
(10) Pub. No.: US 2026/0022076 A1
(43) Pub. Date: Jan. 22, 2026

(54) METAL-CERAMIC SUBSTRATE WITH CONTACT AREA

(71) Applicant: HERAEUS ELECTRONICS GMBH & CO. KG, Hanau (DE)

(72) Inventors: Martin SATTLER, Hanau (DE); Andre SCHWÖBEL, Hanau (DE); Richard WACKER, Hanau (DE); Daniel SCHNEE, Hanau (DE)

(21) Appl. No.: 18/998,031

(22) PCT Filed: Jul. 3, 2023
(86) PCT No.: PCT/EP2023/068188

§ 371 Date: Jan. 23, 2025

(30) Foreign Application Priority Data
Jul. 29, 2022 (EP) 22187740.0

(51) Int. Cl. C04B 37/02

(52) U.S. Cl. CPC C04B 37/021; C04B 37/026; C04B 2237/125; C04B 2237/343; C04B 2237/366; C04B 2237/368; C04B 2237/403; C04B 2237/407

(57) ABSTRACT

A metal-ceramic substrate and an electronic component comprising a metal-ceramic substrate. The metal-ceramic substrate comprises: a) a ceramic body which has a main extension plane, b) a metal layer which is connected to the ceramic body, in a planar manner, the metal layer having a structuring region which comprises: (i) solid material in some areas and (ii) non-solid material in some areas, and c) a contact region comprising silver arranged on the metal layer, wherein, in a cross section through the metal-ceramic substrate perpendicular to the main extension plane, the structuring region has a geometry in which the following requirement is met:

$$A ( {BCD}_{solid} ) / A ( {BCD}_{total} ) > 70 \% ,$$

wherein A (BCDₜₒₜₐₗ) represents the total area of the triangle described by the points B, C and D, and A (BCD_{solid}) represents the area of the triangle described by the points B, C and D which is occupied by solid material.

The present invention relates to a metal-ceramic substrate and an electronic component comprising a metal-ceramic substrate.

Metal-ceramic substrates play an important role in the field of power electronics. They are a crucial element when building electronic components and ensure rapid dissipation of large quantities of heat during operation of said components. Metal-ceramic substrates typically consist of a ceramic layer and a metal layer which is bonded to the ceramic layer.

Several methods are known from the prior art for bonding the metal layer to the ceramic layer. In the so-called DCB (“direct copper bonding”) method, a copper foil is provided superficially with a copper compound (usually copper oxide), which has a lower melting point than copper, by reacting copper with a reactive gas (usually oxygen). When the copper foil treated in this way is applied to a ceramic body and the composite is fired, the copper compound melts and wets the surface of the ceramic body, so that a stable integral bond is achieved between the copper foil and the ceramic body. This method is described, for example, in U.S. Pat. No. 3,744,120 A or DE 2319854 C2.

In an alternative method, metal foils can be bonded to ceramic bodies at temperatures of approximately 650 to 1000° C., wherein a special solder is used which contains a metal having a melting point of at least 700° C. (usually silver) and an active metal. The role of the active metal is to react with the ceramic material and to thus facilitate a bonding of the ceramic material to the remaining solder, forming a reaction layer, while the metal having a melting point of at least 700° C. serves to bond said reaction layer to the metal foil. For example, JP4812985 B2 proposes bonding a copper foil to a ceramic body using a solder containing 50 to 89 weight percent silver, as well as copper, bismuth and an active metal. With this method, it is possible to reliably attach the copper foil to the ceramic body. Alternatively, silver-free solders can be used to bond metal foils to ceramic bodies. These solders are based, for example, on high-melting metals (in particular copper), low-melting metals (such as bismuth, indium or tin), and active metals (such as titanium). Such a technique is proposed, for example, in DE 102017114893 A1. This technique basically results in a new, independent class of compounds, since the basis of the solders used is formed by another metal (copper instead of silver), which leads to changed material properties and results in an adaptation with regard to the other solder components and modified joining conditions.

When constructing electronic components, metal-ceramic substrates are usually equipped with a chip. In order to equip the metal-ceramic substrate with a chip, it is usually necessary that the region of the metal-ceramic substrate to be equipped with the chip is provided with a silver-containing contact region. By providing the silver-containing contact region, the chip can be more easily bonded to the metal-ceramic substrate using common methods such as sintering or soldering. To create the contact region, the metal-ceramic substrate is usually first treated in regions with an etching solution in order to form the desired structuring. The contact region is then provided by partially applying a silver-containing coating to the surface of the structured metal-ceramic substrate.

The metal-ceramic substrates produced in this way are usually exposed to high temperature changes during operation as part of electronic components. While during breaks in operation—depending on the environment—the temperatures can be, for example, −20° C. or less, the temperature of the metal-ceramic substrates can easily rise to over 150° C. during operation. The metal-ceramic substrates are regularly exposed to these temperature differences. Due to the different thermal expansion coefficients of the metal and the ceramic, repeated temperature changes can lead to the metal layer detaching from the ceramic body (peeling), which results in a loss of performance. Therefore, high thermal shock resistance is a key criterion for the suitability of metal-ceramic substrates for applications in electronics, especially in power electronics.

It would therefore be desirable to further increase the thermal shock resistance of metal-ceramic substrates.

An object of the present invention is therefore to provide a metal-ceramic substrate which has an increased resistance to thermal shock.

This object is achieved by the metal-ceramic substrate of claim 1. The invention therefore provides a metal-ceramic substrate comprising
a) a ceramic body comprising a main extension plane,
b) a metal layer which is extensively bonded to the ceramic body, the metal layer comprising a structuring region which comprises
   (i) partially solid material and
   (ii) partially non-solid material
and
c) a silver-comprising contact region arranged on the metal layer,
characterized in that
in a cross section through the metal-ceramic substrate perpendicular to the main extension plane, the structuring region has a geometry that satisfies the following requirement:

$$A ( {BCD}_{solid} ) / A ( {BCD}_{total} ) > 70 \% ,$$

where
A (BCDₜₒₜₐₗ) is the total area of the triangle described by the points B, C and D, and A (BCD_{solid}) is the area of the triangle described by the points B, C and D, which area is occupied by solid material,
wherein points B, C and D are determined as follows:
1. the best-fit line between the ceramic body and the metal layer is determined;
2. the contour line is determined that separates the solid material from the non-solid material;
3. on a perpendicular to the best-fit line, at a distance of 150 um from the best-fit line, point A is determined at which the perpendicular to the best-fit line intersects the contour line;
4. on a perpendicular to the best-fit line, at a distance of 80 um from the best-fit line, point B is determined at which the perpendicular to the best-fit line intersects the contour line;
5. on a straight line passing through points A and B, point C is determined at which the straight line intersects the best-fit line;
6. on a perpendicular to the best-fit line, which passes through point B, point D is determined at which the perpendicular intersects the best-fit line.

Furthermore, the invention relates to an electronic component comprising such a metal-ceramic substrate and a chip.

The metal-ceramic substrate according to the invention comprises a ceramic body comprising a main extension plane.

The ceramic body is preferably a body formed from ceramic. The body can have any geometry, but is preferably designed as a cuboid. The ceramic body comprises boundary surfaces, in the case of a cuboid six boundary surfaces. The main boundary surface is preferably referred to herein as the boundary surface with the largest surface area, which is extensively bonded to the metal layer. The main boundary surface preferably lies in the main extension plane or runs parallel to it. Accordingly, the main extension plane of the ceramic body is preferably understood to be a plane that runs parallel to the main boundary surface of the ceramic body or encloses it.

The ceramic of the ceramic body is preferably an insulating ceramic. According to a preferred embodiment, the ceramic is selected from the group consisting of oxide ceramics, nitride ceramics, and carbide ceramics. According to a further preferred embodiment, the ceramic is selected from the group consisting of metal oxide ceramics, silicon oxide ceramics, metal nitride ceramics, silicon nitride ceramics, boron nitride ceramics, and boron carbide ceramics. According to a particularly preferred embodiment, the ceramic is selected from the group consisting of aluminum nitride ceramics, silver nitride ceramics, and aluminum oxide ceramics (such as ZTA (“zirconia toughened alumina”) ceramics). According to a further very particularly preferred embodiment, the ceramic body consists of (1) at least one element selected from the group consisting of silicon and aluminum, (2) at least one element selected from the group consisting of oxygen and nitrogen, optionally (3) at least one element selected from the group consisting of (3a) rare earth metals, (3b) metals of the second main group of the periodic table of elements, (3c) zirconium, (3d) copper, (3e) molybdenum and (3f) silicon, and optionally (4) unavoidable impurities. According to yet another very particularly preferred embodiment, the ceramic body is free of bismuth, gallium, and zinc.

The ceramic body preferably has a thickness of 0.05-10 mm, more preferably in the range of 0.1-5 mm, and particularly preferably in the range of 0.15-3 mm.

The metal-ceramic substrate according to the invention comprises a metal layer which is extensively bonded to the ceramic body, wherein the metal layer has a structuring region which comprises (i) partially solid material and (ii) partially non-solid material.

The metal layer is preferably integrally bonded to the ceramic body. According to a preferred embodiment, the metal layer is bonded to the ceramic body via a DCB (Direct Copper Bonding) method. According to a further preferred embodiment, the metal layer is bonded to the ceramic body via a brazing process. The brazing process can, for example, be an AMB (Active Metal Brazing) method, preferably using silver-free brazing alloys (the silver content is then, for example, less than 1.0 weight percent based on the solids content of the brazing alloy) or silver-containing brazing alloys (the silver content is then, for example, at least 50 weight percent based on the solids content of the brazing alloy). Consequently, the metal layer may also comprise a bonding layer in contact with the ceramic body. The bonding layer can be, for example, a solder layer (in particular a brazing layer) or a diffusion layer.

The metal layer is extensively bonded to the ceramic body. Accordingly, the metal layer is preferably extensively bonded to the main boundary surface of the ceramic body. The metal layer is preferably not bonded to the entire main boundary surface of the ceramic body. In particular, it can be provided that the main boundary surface of the ceramic body is larger than the surface of the metal layer bonded to the ceramic body. In these cases, the main boundary surface of the ceramic body protrudes. In addition, the metal layer is preferably structured. Structuring is preferably understood to mean recesses in the metal layer in order to separate individual portions of the metal layer from one another and thus to electrically isolate them. Such structuring is usually created using etching techniques.

Accordingly, the metal layer has a structuring region. The structuring region is understood to be a portion of the metal layer that contains a structuring. A structuring is preferably a recess in the metal layer.

The metal layer further has on the upper side (preferably facing away from the main boundary surface of the ceramic body) a main metal surface parallel to the main boundary surface of the ceramic body. This main metal surface therefore comprises metal of the metal layer, which is interrupted by the recess in the structuring region.

The structuring region has a region comprising solid material and a region comprising non-solid material.

The region comprising solid material preferably contains at least one member of the group consisting of (i) metal of the metal layer (optionally including a bonding layer (if present, for example in the case of AMBs), (ii) metal of the contact region (in particular silver) and (iii) material of the ceramic body. Therefore, the solid material preferably contains (i) metal of the metal layer (optionally including a bonding layer) and optionally (ii) metal of the contact region (in particular silver) and/or (iii) material of the ceramic body.

According to a preferred embodiment, the structuring region between the main metal surface (excluding the contact region) and the main boundary surface of the ceramic body does not comprise the main metal of the contact region, in particular no silver. According to a further preferred embodiment, the solid material of the structuring region between the main metal surface (excluding the contact region) and the main boundary surface of the ceramic body does not comprise a deposition of the main metal of the contact region, in particular silver. Accordingly, according to a particularly preferred embodiment, the solid material of the structuring region between the main metal surface (excluding the contact region) and the main boundary surface of the ceramic body does not have a layer made of the main metal of the contact region, in particular silver. The main metal of the contact region is preferably the metal that has the highest weight proportion in the contact region.

The region comprising non-solid material preferably contains gaseous material. Therefore, the non-solid material preferably comprises gaseous material. The non-solid material is preferably gaseous material with which the recess in the metal layer is filled. This gaseous material usually comes from the ambient atmosphere. Preferably, the gaseous material therefore contains at least one element selected from the group consisting of nitrogen, oxygen and noble gases. The gaseous material is very particularly preferably air.

According to a preferred embodiment, the recess extends in a direction perpendicular to the main boundary surface of the ceramic body from the main boundary surface of the ceramic body to the main metal surface. The recess preferably forms a channel which is filled to at least 50 percent by volume, more preferably to at least 80 percent by volume, even more preferably to at least 90 percent by volume, particularly preferably to at least 95 percent by volume and very particularly preferably to at least 99 percent by volume, in particular completely, with non-solid material.

The metal layer preferably comprises at least one metal selected from the group consisting of copper, aluminum and molybdenum. According to a particularly preferred embodiment, the metal layer comprises at least one metal which is selected from the group consisting of copper and molybdenum. According to a very particularly preferred embodiment, the metal layer comprises copper. According to a further preferred embodiment, the metal layer consists of copper and unavoidable impurities. According to a further preferred embodiment, the proportion of copper is at least 60 weight percent, more preferably at least 65 weight percent, even more preferably at least 70 weight percent and particularly preferably at least 75 weight percent, in relation to the total weight of the metal layer (preferably including any bonding layer that may be present).

According to a preferred embodiment, the metal layer is produced by integrally bonding a copper foil (preferably a foil made of high-purity copper) to a ceramic body. According to a preferred embodiment, the bonding can be performed via a DCB (Direct Copper Bonding) method or via a brazing method. The brazing process can, for example, be an AMB (Active Metal Brazing) method, preferably using silver-free brazing alloys (the silver content is then, for example, less than 1.0 weight percent based on the solids content of the brazing alloy) or silver-containing brazing alloys (the silver content is then, for example, at least 50 weight percent based on the solids content of the brazing alloy). In this case, the metal layer may comprise, in addition to the copper originating from the copper foil, also metals from a bonding layer, in particular metals from a solder layer (for example a brazing layer) or a diffusion layer.

The metal layer preferably has a thickness in the range of 0.01-10 mm, particularly preferably in the range of 0.03-5 mm, and very particularly preferably in the range of 0.05-3 mm.

The metal-ceramic substrate according to the invention has a silver-comprising contact region arranged on the metal layer. The contact region preferably serves to facilitate the bonding of a semiconductor to the metal layer. Semiconductors are preferably bonded to the metal layer by sintering, soldering or gluing. Since in particular the attachment of semiconductors to the metal of the metal layer of a metal-ceramic substrate is not easily possible, the metal layer is preferably provided with a contact region. The contact region is preferably made of silver or a silver-containing alloy. In the case of a silver-containing alloy, it contains at least 50 weight percent silver, in relation to the weight of the silver alloy. Preferably, a contact region is provided on the metal layer of the metal-ceramic substrate at all positions where the metal-ceramic substrate is later to be populated with semiconductors. The contact region can be formed on the metal layer of the metal-ceramic substrate using different techniques. For example, it is possible to provide the contact region by deposition. The deposition can be, for example, a physical deposition or a chemical deposition. For example, gas phase deposition can be considered as a physical deposition. Preferred methods for gas phase deposition are in particular electron beam deposition, laser beam deposition, arc discharge deposition or cathode sputtering. In chemical deposition, the contact region is preferably created by applying a composition containing silver or a silver precursor to the metal layer. For example, a composition containing silver can be fired to create a sintered bond between the silver contained in the composition and the metal of the metal layer. For example, a composition containing a silver precursor may be subjected to a treatment that releases silver and allows adsorption of the silver to the metal layer. This treatment can be done, for example, by contacting the silver precursor with the metal layer. Methods for depositing silver or silver compounds to produce contact regions on the metal layer of metal-ceramic substrates are known to those skilled in the art.

In a cross section through the metal-ceramic substrate perpendicular to the main extension plane, the structuring region of the metal-ceramic substrate has a geometry that satisfies the following requirement:

$$A ( {BCD}_{solid} ) / A ( {BCD}_{total} ) > 70 \% ,$$

where
A (BCDₜₒₜₐₗ) is the total area of the triangle described by the points B, C and D, and A (BCD_{solid}) is the area of the triangle described by the points B, C and D, which area is occupied by solid material,

According to a preferred embodiment, the structuring region of the metal-ceramic substrate in a cross section through the metal-ceramic substrate perpendicular to the main extension plane has a geometry that satisfies the ratio A (BCD_{solid})/A (BCDₜₒₜₐₗ)>75%, more preferably >80%, even more preferably >85%, particularly preferably >90% and very particularly preferably >95%.

According to a further preferred embodiment, the structuring region of the metal-ceramic substrate in a cross section through the metal-ceramic substrate perpendicular to the main extension plane has a geometry in which the ratio A (BCD_{solid})/A (BCDₜₒₜₐₗ) is in the range of 75-100%, particularly preferably in the range of 90-100% and most preferably in the range of 95-99%.

To determine the triangle described by points B, C and D, a cross section of the structuring region of the metal-ceramic substrate is observed. The cross section runs perpendicular to the main extension plane of the ceramic body. Preferably, the observation of the cross section can be carried out by cutting the metal-ceramic substrate perpendicular to the main extension plane of the ceramic body and taking a picture of the cross section thus obtained using a scanning electron microscope.

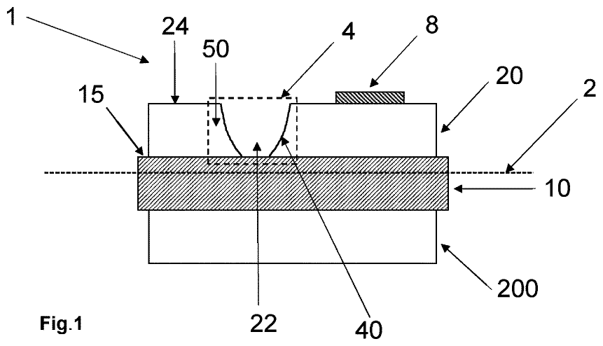

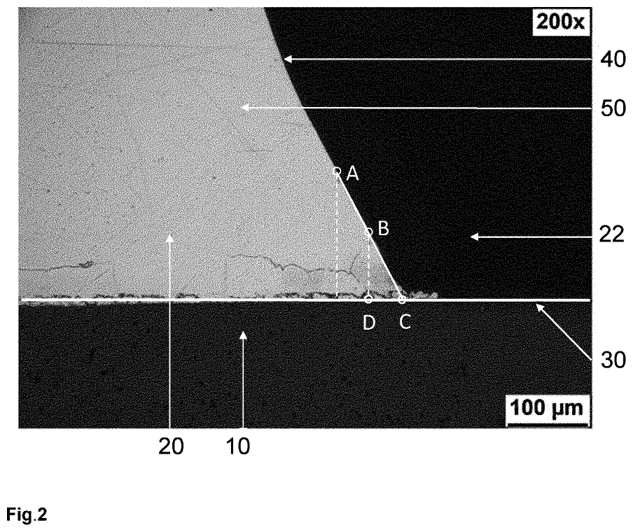

The points B, C and D of the triangle can be determined in the cross section as described below. For illustration purposes, reference is made to FIGS. 1 and 2 by way of example.

FIG. 1 shows a schematic representation of a generic metal-ceramic substrate.

FIG. 2 shows a part of a cross section through a metal-ceramic substrate according to the invention.

The metal-ceramic substrate 1 shown in FIG. 1 comprises a ceramic body 10. A main extension plane 2 of the ceramic body 10 is indicated (as a line) with the reference numeral 2. The ceramic body 10 comprises a main boundary surface 15. The metal-ceramic substrate 1 comprises a metal layer 20 which is extensively bonded to the main boundary surface 15 of the ceramic body 10. In the embodiment according to FIG. 1, the metal-ceramic substrate 1 further comprises a further metal layer 200 which is extensively bonded to the ceramic body 10.

On the metal layer 20 there is a contact region 8 comprising silver. The metal layer 20 comprises a structuring. This is formed by a recess 22 in the metal layer 20. The recess 22 contains non-solid material. The structuring region 4 partially comprises the metal layer 20 and the recess 22. Therefore, the structuring region 4 comprises partially solid material 50, which is formed by the metal of the metal layer 20, and non-solid material (for example gaseous material) with which the recess 22 is filled. The gaseous material is usually ambient air. The solid material 50 is separated from the non-solid material of the recess 22 by a contour line 40. The metal layer 20 has, on the upper side facing away from the main boundary surface 15 of the ceramic, a main metal surface 24 parallel to the main boundary surface 15 of the ceramic. This main metal surface 24 comprises metal of the metal layer 20, which is interrupted by the recess 22 in the structuring region. The recess 22 extends in a direction perpendicular to the main boundary surface 15 of the ceramic from the main boundary surface 15 of the ceramic to the main metal surface 24 and preferably forms a channel which is completely or predominantly filled with non-solid material.

In the part of a cross section through a metal-ceramic substrate according to the invention shown in FIG. 2, a portion of a structuring region can be seen. Shown is a region of the ceramic body which is extensively bonded to a region of a metal layer 20. The contour line 40 separates the solid material 50 from the non-solid material of the recess 22 in the metal layer 20.

The determination of points B and C of the line BC in the cross section is preferably carried out in several steps:

In a first step, the best-fit line 30 between the ceramic body 10 and the metal layer 20 is determined. For this purpose, the region of the ceramic body 10 and the region of the metal layer 20 are visually determined and the best-fit line 30 is defined as the boundary between the ceramic body 10 and the metal layer 20 that can be observed in the cross section.

In a second step, the contour line 40 is determined which separates the solid material 50 from the non-solid material of the recess 22. The solid material 50 is determined visually; this is usually the material of the metal layer 20. The non-solid material is also determined visually. The non-solid material is usually a gaseous material with which the structuring is filled as a recess 22 in the metal layer 20.

In a third step, on a perpendicular to the best-fit line 30, at a distance of 150 um from the best-fit line 30, point A is determined at which point the perpendicular to the best-fit line 30 intersects the contour line 40.

In a fourth step, on a perpendicular to the best-fit line 30 at a distance of 80 um from the best-fit line 30, point B is determined at which point the perpendicular to the best-fit line 30 intersects the contour line 40.

In a fifth step, on a straight line passing through points A and B, point C is determined at which the straight line intersects the best-fit line 30.

In a sixth step, on a perpendicular to the best-fit line 30, which passes through point B, point D is determined at which the perpendicular intersects the best-fit line 30.

The cutting of the metal-ceramic substrate perpendicular to the main extension plane of the ceramic body and the recording of the cross section thus obtained through a light microscope (incident light/bright field) are preferably carried out as described below:

In a first step, a cuboid sample blank having a rectangular base in the range of 100 mm² to 400 mm² is first cut out of the metal-ceramic substrate to be examined by sawing using a diamond saw blade at a low rotational speed and using a lubricant (Exakt) perpendicular to a plane spanned by the main metal surface of the metal layer of the metal-ceramic substrate. The sample blank accordingly has a sample surface which is supplied to the investigation. This sample surface therefore runs perpendicular to the plane spanned by the main metal surface of the metal layer of the metal-ceramic substrate before sawing. It therefore has portions on the ceramic body and the metal layer (including the bonding layer optionally provided). The sample blank is first embedded in a casting mold with a low-shrinkage epoxy resin (Caldo-Fix, Struers), wherein the sample surface is oriented perpendicular to the mold wall. The epoxy resin is then cured at 75° C. in a drying cabinet. After curing, the sample surface of the sample blank is mechanically polished with an automated polishing device (Tegrapole, Struers) in order to achieve a roughness of 1 μm or less.

In a second step, a structuring region in the metal layer is identified in the analysis zone using a light microscope (Leica, DM6000M, incident light/bright field) at a magnification of 200×, which region comprises partially solid material and partially non-solid material. Solid material and non-solid material can be clearly distinguished in the structuring region due to the different colors.

The areas A (BCD_{solid}) and A (BCDₜₒₜₐₗ) are preferably determined in a routine manner, for example using image evaluation software (e.g., IMS Client, Imagic).

Preferably, the term “in a cross section” as used herein refers to a (preferably representative) total of cross sections, particularly preferably to at least ten cross sections, very particularly preferably to not more than 20 cross sections and in particular to ten cross sections. The cross sections preferably run parallel to one another and are evenly spaced from one another. Therefore, to determine the ratio A (BCD_{solid})/A (BCDₜₒₜₐₗ) for a metal-ceramic substrate to be observed, the following procedure is preferably used:
1. At least ten, particularly preferably ten, different cross sections of the structuring region are examined;
2. the ratio A (BCD_{solid})/A (BCDₜₒₜₐₗ) is determined for each of these cross sections; and
3. the ratios A (BCD_{solid})/A (BCDₜₒₜₐₗ) are averaged for each of these cross sections to obtain the ratio A (BCD_{solid})/A (BCDₜₒₜₐₗ) for the metal-ceramic substrate under observation.

According to a preferred embodiment, the sample standard deviation SSD of the ratio A (BCD _{solid})/A (BCDₜₒₜₐₗ) over at least ten different cross sections of at least one structuring region of the metal layer, more preferably over no more than 20 different cross sections of at least one structuring region of a metal layer, and most preferably over ten different cross sections of at least one structuring region of a metal layer, is not more than 10%, more preferably not more than 7%, particularly preferably not more than 5% and very particularly preferably not more than 2%. The sample standard deviation SSD is determined using the following formula:

$$SSD = \sqrt{\frac{1}{n - 1} {\sum }_{i = 1}^{n} {( {X}_{i} - \overline{X} )}^{2}} ,$$

where:
n=number of individual values for the ratio A (BCD-_{solid})/A (BCD-ₜₒₜₐₗ),
Xᵢ=individual value for the ratio A (BCD-_{solid})/A (BCD-ₜₒₜₐₗ) and
X̅=mean of the individual values for the ratio A (BCD-_{solid})/A (BCD-ₜₒₜₐₗ).

Surprisingly, it was found that metal-ceramic substrates with the geometry according to the invention have an increased thermal shock resistance compared to metal-ceramic substrates from the prior art. These metal-ceramic substrates have a high proportion of solid material in the metal layer at the boundary to the surface of the ceramic body. In contrast, it was found that the proportion of solid material in the metal layer at the boundary to the surface of the ceramic body is significantly lower in metal-ceramic substrates from the prior art, as long as they have a silver-comprising contact region arranged on the metal layer.

Without being bound to an explanation, this could be due to the fact that in the prior art, the metal-ceramic substrate produced is usually first structured and then silver-plated on the surface to create the contact region. Silver plating is usually done by dipping the structured metal-ceramic substrate into a bath containing a solution containing silver ions. Metal ions are electrochemically dissolved from the metal layer of the metal-ceramic substrate and replaced by silver ions. Within the scope of the invention, it was observed that in this process silver ions are predominantly deposited on the surface of the metal-ceramic substrate, but the metal ions of the metal layer are predominantly dissolved out in a region near the ceramic body (an effect that cannot be prevented by masking the structuring, since the masking is washed away by the solution containing silver ions due to edge-side structuring in the metal layer). This effect is particularly pronounced when the metal layer in the region adjacent to the ceramic body is already structured and therefore no longer homogeneous. This results in the removal of solid material-in particular the metal of the metal foil-from the metal foil in the region close to the ceramic body and thus creates a weak point for the detachment of the metal layer from the ceramic body, which has a detrimental effect on the thermal shock resistance. According to the invention, however, a structuring region is created which has sufficient amounts of solid material in the region close to the ceramic body, whereby detachment of the metal layer from the ceramic body can be prevented and an improvement in the thermal shock resistance can be achieved.

According to a preferred embodiment, the metal-ceramic substrate comprises a further (second) metal layer which is extensively bonded to the ceramic body. The further metal layer is preferably extensively bonded to the boundary surface facing away from the main boundary surface of the ceramic (and preferably running parallel thereto). The further (second) metal layer can be of the same nature as the (first) metal layer or can differ in its nature from the (first) metal layer. For the nature of the further (second) metal layer, reference is made to the above explanations.

The metal-ceramic substrate according to the invention can in particular be used for applications in electronics, especially for the field of power electronics.

The invention therefore also provides an electronic component which has a metal-ceramic substrate described above.

According to a preferred embodiment, such an electronic module comprises a base plate. Said base plate is preferably extensively bonded to the metal layer of the metal-ceramic substrate. Alternatively, the metal layer of the metal-ceramic substrate can be designed as a heat sink. According to a further preferred embodiment, the electronic component comprises at least one chip. The at least one chip is preferably extensively bonded to the silver-comprising contact region arranged on the metal layer. According to a further preferred embodiment, the electronic component comprises a metal-ceramic substrate comprising a first metal layer and a second metal layer (wherein the first metal layer is preferably opposite the second metal layer), a base plate, and at least one chip, wherein the at least one chip is bonded to the first metal layer of the metal-ceramic substrate via the silver-comprising contact region arranged on the metal layer and the base plate is bonded to the second metal layer of the metal-ceramic substrate.

The metal-ceramic substrate according to the invention can be obtained by different manufacturing processes.

According to a preferred embodiment, the method is a method for producing a metal-ceramic substrate provided with a structuring and a contact region comprising silver, said method comprising the steps of:
a) providing a metal-ceramic substrate comprising
   a1) a ceramic body and
   a2) a metal layer extensively bonded to the ceramic body,
b) applying a first masking to the metal layer,
c) depositing a silver-containing layer on the unmasked regions of the metal layer to obtain a contact region comprising silver,
d) removing the first masking,
e) applying a second masking to the metal layer,
f) etching unmasked regions of the metal layer while maintaining a pattern and
g) removing the second masking.

In this method, therefore, a metal-ceramic substrate is preferably first provided. This metal-ceramic substrate has a ceramic body and a metal layer that is extensively bonded to the ceramic body. The metal-ceramic substrate can be a standard metal-ceramic substrate. The ceramic body and the metal layer may have a composition as described above with respect to the metal-ceramic substrate. The metal layer can preferably be integrally bonded to the ceramic body, as also described above with respect to the metal-ceramic substrate.

In the method, a first masking is preferably applied to the metal layer. The first masking serves to protect the masked regions of the metal layer from deposition of a silver-containing layer in the subsequent step. This ensures that a silver-containing layer is deposited only on the unmasked regions of the metal layer of the metal-ceramic substrate. Consequently, the masking is designed in such a way that no silver-containing layer is deposited on the masked regions of the metal layer of the metal-ceramic substrate. The type of masking is not limited further. The masking can, for example, be a standard negative mask or positive mask. The masking can be created, for example, by a foil (or a dry film) or a liquid, which is optionally printed or sprayed onto the surface of the metal-ceramic substrate in certain regions. For example, standard etching resists can be used. These etching resists preferably contain a curable polymer (for example a light-curable polymer). According to one possible embodiment, a photosensitive film is applied to the metal layer of the metal-ceramic substrate and is then exposed at the regions to be masked in order to obtain the first masking. The unexposed regions of the photosensitive film can then be removed in a conventional manner (for example using a sodium carbonate solution).

After the application of the first masking, a silver-containing layer is preferably deposited on the unmasked regions of the metal layer to obtain a contact region comprising silver. The silver-containing layer is preferably a layer consisting of silver or a silver alloy, particularly preferably silver. The silver-containing layer is preferably deposited in a conventional manner. The silver-containing layer can be deposited, for example, electrochemically, currentlessly or chemically. Preference is given to chemical deposition by applying a silver-containing solution with a charge exchange between the metals, wherein metal of the metal layer partially dissolves while the silver in solution is deposited. According to a preferred embodiment, the silver-containing solution contains a silver salt and particularly preferably silver nitrate. According to a preferred embodiment, the silver-containing solution is an acidic solution of silver nitrate and particularly preferably a nitric acid solution of silver nitrate. The concentration of silver in the nitric acid solution can, for example, be in the range of 0.5-1.5 g/l, particularly preferably in the range of 0.6-1.4 g/l and very particularly preferably in the range of 0.8-1.2 g/l.

Preferably, after depositing a silver-containing layer on the unmasked regions of the metal layer to obtain a contact region comprising silver, the first masking is removed. The first masking can be removed in a standard manner. For this purpose, the metal-ceramic substrate can be treated with an alkaline solution (e.g., a 2.5% sodium hydroxide solution) to remove the first masking.

After removing the first masking, a second masking is preferably applied to the metal layer. The second masking serves to protect the masked regions of the metal layer of the metal-ceramic substrate from etching in the subsequent step. This ensures that only those regions of the metal layer of the metal-ceramic substrate that are unmasked and intended for patterning are accessible for etching. Consequently, the masking is created in such a way that no etching of the masked regions of the metal layer occurs. According to a preferred embodiment, the second masking is applied to regions of the metal-ceramic substrate to which the first masking has not already been applied. The type of masking is not limited further. The masking can, for example, be a standard negative mask or positive mask. The masking can be created, for example, by a foil (or a dry film) or a liquid, which is optionally printed or sprayed onto the surface of the metal-ceramic substrate in certain regions. For example, standard etching resists can be used. These etching resists preferably contain a curable polymer (for example a light-curable polymer). According to one possible embodiment, a photosensitive film is applied to the partially silver-coated surface of the metal-ceramic substrate and is then exposed at the regions to be masked in order to obtain the second masking. The unexposed regions of the photosensitive film can then be removed in a conventional manner (for example using a sodium carbonate solution).

After the second masking has been applied to the metal layer, unmasked regions of the metal layer are preferably etched to obtain a structuring. Etching is preferably carried out in a standard professional manner. Etching is therefore preferably carried out using a standard etching solution. According to a preferred embodiment, the etching solution is selected from the group consisting of FeCl₃ etching solutions and CuCl₂ etching solutions. If necessary, an additional etching solution can be used, for example to structure unmasked regions of an optionally contained bonding layer. According to a preferred embodiment, the further etching solution can be selected from the group consisting of etching solutions containing hydrogen peroxide and etching solutions containing ammonium peroxodisulfate. For example, the further etching solution may be an etching solution containing ammonium fluoride and fluoroboric acid (for example HBF₄) as well as hydrogen peroxide and/or ammonium peroxodisulfate.

Preferably, after etching unmasked regions of the metal layer while maintaining a structuring, the second masking is removed. The second masking can be removed in a standard manner. For this purpose, the metal-ceramic substrate can be treated with an alkaline solution (e.g., a 2.5% sodium hydroxide solution) to remove the second masking.

The method described herein makes it possible to obtain a metal-ceramic substrate which is provided with a structure and a contact region comprising silver. By creating a silver-comprising contact region, the chip can be more easily bonded to the metal-ceramic substrate using common methods such as sintering or soldering. The metal-ceramic substrate obtained in this way is characterized by a particularly high resistance to thermal shock.

### EXEMPLARY EMBODIMENTS

The present invention is described in more detail below by means of exemplary embodiments, which, however, should not be understood as limiting.

### Example

For the example, a metal-ceramic substrate was used in which a ceramic body made of a silicon nitride ceramic with the dimensions 177.8×139×0.32 mm was bonded on both sides to a copper layer with the dimensions 170×132×0.3 mm using an AMB (Active Metal Brazing) method. This copper-ceramic substrate was first cleaned after production.

A photosensitive film was then applied to both copper layers of the copper-ceramic substrate using a hot roll laminator. The photosensitive film was exposed to 30 mJ/cm² in each of the regions to be masked in order to cure the polymer contained in the photosensitive film and obtain the first masking. Subsequently, the unexposed regions of the photosensitive film were removed wet-chemically using a sodium carbonate solution (concentration=10 g/l). After applying the first masking, the copper-ceramic substrate was cleaned by rinsing. Subsequently, silver-containing contact regions were deposited on the unmasked regions of the copper layers of the copper-ceramic substrate. For this purpose, the copper-ceramic substrate provided with the first masking was first pretreated with a first solution containing hydrogen peroxide and sulfuric acid and then contacted with a nitric acid silver nitrate solution (silver content=1.0 g/l). After deposition of the silver-containing contact regions, the copper-ceramic substrate was carefully rinsed with water to remove any residues. The first masking was then removed in a stripping system using a 2.5% sodium hydroxide solution.

Subsequently, a photosensitive film was applied to both copper layers of the copper-ceramic substrate, each of which had silver-containing contact regions, using a hot roll laminator. The photosensitive film was exposed to 30 mJ/cm² in each of the regions to be masked in order to harden the polymer contained in the photosensitive film and obtain the second masking. The unexposed points of the photosensitive film were then removed wet-chemically using a sodium carbonate solution (concentration=10 g/l). After applying the second masking, the copper-ceramic substrate was again cleaned by rinsing. Subsequently, the unmasked regions of the copper layers of the copper-ceramic substrate provided with silver-containing contact regions were wet-chemically etched. For this purpose, the copper-ceramic substrate was sprayed in an etching system with a hydrochloric acid copper chloride solution (copper ion content=160 g/l) containing hydrogen peroxide. Etching was carried out at a temperature of 50° C. and a spray pressure of 2.8 bar. By etching, material was removed from the unmasked regions of the copper layer of the copper-ceramic substrate. The metal-ceramic substrates were then rinsed. Then, unmasked regions of the bonding layer contained in the metal-ceramic substrate were also wet-chemically etched. For this purpose, the metal-ceramic substrate was again sprayed in an etching system with an etching solution containing ammonium fluoride, fluoroboric acid and hydrogen peroxide. The copper-ceramic substrate was then rinsed and dried. The second masking was then removed in a stripping system using a 2.5% sodium hydroxide solution.

The resulting copper-ceramic substrate was laser cut into individual parts with the dimensions (20.5×17.0 mm) and could then be used for further investigations and the production of an electronic component.

### Comparative Example

The comparative example was carried out as in the example, reversing the order of the steps: (i) depositing a silver-containing layer on the unmasked regions of the copper layer to obtain a contact region comprising silver and (ii) etching unmasked regions of the copper layer to obtain a structuring.

For the comparative example, a metal-ceramic substrate analogous to the example was used in which a ceramic body made of a silicon nitride ceramic with the dimensions 177.8×139×0.32 mm was bonded on both sides to a copper layer with the dimensions 170×132×0.3 mm using an AMB (Active Metal Brazing) process. This copper-ceramic substrate was first cleaned after production.

A photosensitive film was then applied to both copper layers of the copper-ceramic substrate using a hot roll laminator. The photosensitive film was exposed to 30 mJ/cm² in each of the regions to be masked in order to cure the polymer contained in the photosensitive film and obtain the first masking. Subsequently, the unexposed regions of the photosensitive film were removed wet-chemically using a sodium carbonate solution (concentration=10 g/l). After applying the first masking, the copper-ceramic substrate was cleaned by rinsing. Subsequently, the unmasked regions of the copper layers of the copper-ceramic substrate were wet-chemically etched. For this purpose, the copper-ceramic substrate was sprayed in an etching system with a hydrochloric acid copper chloride solution (copper ion content=160 g/l) containing hydrogen peroxide. Etching was carried out at a temperature of 50° C. and a spray pressure of 2.8 bar. By etching, material was removed from the unmasked regions of the copper layers of the copper-ceramic substrate. The metal-ceramic substrates were then rinsed. Then, unmasked regions of the bonding layer contained in the metal-ceramic substrate were also wet-chemically etched. For this purpose, the metal-ceramic substrate was again sprayed in an etching system with an etching solution containing ammonium fluoride, fluoroboric acid and hydrogen peroxide. The copper-ceramic substrate was then rinsed and dried. The second masking was then removed in a stripping system using a 2.5% sodium hydroxide solution.

A photosensitive film was then applied to both etched surfaces of the copper-ceramic substrate using a hot roll laminator. The photosensitive film was exposed to 30 mJ/cm² in each of the regions to be masked in order to harden the polymer contained in the photosensitive film and obtain the second masking. The unexposed points of the photosensitive film were then removed wet-chemically using a sodium carbonate solution (concentration=10 g/l). After applying the second masking, the copper-ceramic substrate was again cleaned by rinsing. Subsequently, silver-containing contact regions were deposited on the unmasked regions of the copper layers of the copper-ceramic substrate. For this purpose, the copper-ceramic substrate provided with the second masking was first pretreated with a first solution containing hydrogen peroxide and sulfuric acid and then contacted with a nitric acid silver nitrate solution (silver content=1.0 g/l). After deposition of the silver-containing contact regions, the copper-ceramic substrate was carefully rinsed with water to remove any residues. The second masking was then removed in a stripping system using a 2.5% sodium hydroxide solution.

The resulting copper-ceramic substrate was laser cut into individual parts with the dimensions (20.5×17.0 mm) and could then be used for further investigations and the production of an electronic component.

### Evaluation

For the metal-ceramic substrates obtained in the example and the comparative example, the ratio A (BCD_{solid})/A (BCDₜₒₜₐₗ) was determined. For this purpose, as described herein, the metal-ceramic substrates were cut perpendicular to the main extension plane of the respective ceramic bodies and images of the cross sections thus obtained were taken using a light microscope. Points A, B, C and D were determined in the cross sections. Then, the ratio A (BCD_{solid})/A (BCDₜₒₜₐₗ) was determined for each of the metal-ceramic substrates. For this purpose, ten different cross sections of structuring regions in the metal layer of the relevant metal-ceramic substrate were investigated, the ratio A (BCD_{solid})/A (BCDₜₒₜₐₗ) for each of these cross sections was determined, and the mean of the ratios A (BCD_{solid})/A (BCDₜₒₜₐₗ) for each of these cross sections was calculated to arrive at the ratio A (BCD_{solid})/A (BCDₜₒₜₐₗ) for the respective metal-ceramic substrate. Furthermore, the standard deviation SSD was determined.

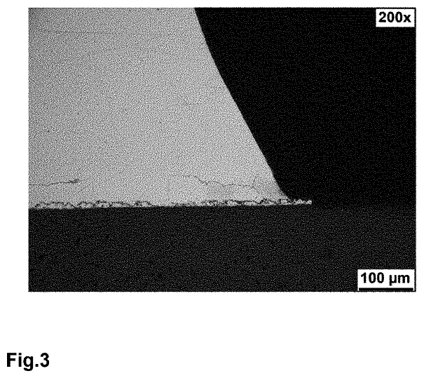

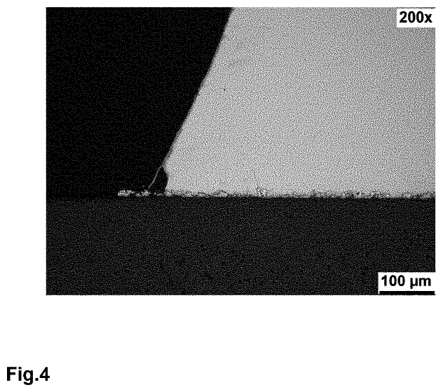

FIG. 3 shows an example of a light microscopic image of the cross section of a structuring region of a metal-ceramic substrate according to the example, while FIG. 4 shows an example of a light microscopic image of the cross section of a structuring region of a metal-ceramic substrate according to the comparative example.

The results are shown in Table 1.

TABLE 1

| | A (BCD_{solid})/ | Standard |
|---|---|---|
| | A (BCDₜₒₜₐₗ) | deviation SSD |
| Example | 97.2% | 0.4% |
| Comparative example | 67.3% | 11.7% |

The metal-ceramic substrates were tested for their thermal shock resistance. For this purpose, thermal shock resistance tests were carried out.

### Thermal Shock Resistance Test

In preparation for the thermal shock resistance test, ultrasound microscopy (PVA Tepla SAM300) was first used to check whether the metal-ceramic substrates were in perfect condition. For the test, only metal-ceramic substrates were used that showed no delamination between the ceramic body and the metal layer or other deformations that could lead to delamination of the metal layer from the ceramic body (e.g., cracks). To test the thermal shock resistance, the metal-ceramic substrates were repeatedly exposed to a cold liquid (temperature −65° C., Galden Do2TS) and a hot liquid (temperature +150° C., Galden Do2TS) in a cycling chamber (ESPEC TSB-21 51) for a period of five minutes each. The metal-ceramic substrates were checked again every 1000 cycles for delamination and other deformations by means of ultrasound microscopy (PVA Tepla SAM300). The test was terminated after 3000 cycles. The metal-ceramic substrates were then again examined for delamination and other deformations by means of ultrasound microscopy (PVA Tepla SAM300). The condition of the respective metal-ceramic substrates after the thermal shock resistance test was compared with the condition of the metal-ceramic substrates before the thermal shock resistance test with regard to delamination and other deformations. Delaminations and other deformations (e.g., cracks) were visible as white discolorations in the ultrasound image.

The results are shown in Table 2.

TABLE 2

| | Result of the thermal shock resistance test |
|---|---|
| Example | Very good: No delaminations were visible |
| Comparative | Poor: Pronounced delaminations were visible |
| example | at the corners of the metal-ceramic substrate |

The results show that the metal-ceramic substrate according to the invention is clearly superior to the metal-ceramic substrate of the comparative example with regard to thermal shock resistance.

### List of Reference Numerals

1 metal-ceramic substrate
2 main extension plane
4 structuring region
8 contact region
10 ceramic body
15 main boundary surface
20 metal layer
22 recess
24 metal main surface
40 contour line
50 solid material
200 further metal layer

1. A metal-ceramic substrate comprising:
a) a ceramic body comprising a main extension plane;
b) a metal layer which is extensively bonded to the ceramic body, the metal layer comprising a structuring region which comprises.
(i) partially solid material and
(ii) partially non-solid material, and
c) a silver-comprising contact region arranged on the metal layer,
wherein
in a cross section through the metal-ceramic substrate perpendicular to the main extension plane, the structuring region has a geometry that satisfies the following requirement:
$$A ( {BCD}_{solid} ) / A ( {BCD}_{total} ) > 70 \% ,$$
where
A (BCDₜₒₜₐₗ) is the total area of the triangle described by the points B, C and D, and A (BCD_{solid}) is the area of the triangle described by the points B, C and D, which area is occupied by solid material,
wherein points B, C and D are determined as follows:
1. the best-fit line between the ceramic body and the metal layer is determined;
2. the contour line is determined that separates the solid material from the non-solid material;
3. on a perpendicular to the best-fit line, at a distance of 150 μm from the best-fit line, point A is determined at which the perpendicular to the best-fit line intersects the contour line;
4. on a perpendicular to the best-fit line, at a distance of 80 μm from the best-fit line, point B is determined at which the perpendicular to the best-fit line intersects the contour line;
5. on a straight line passing through points A and B, point C is determined at which the straight line intersects the best-fit line; and
6. on a perpendicular to the best-fit line, which passes through point B, point D is determined at which the perpendicular intersects the best-fit line.

2. The metal-ceramic substrate according to claim 1, wherein the ceramic of the ceramic body is selected from the group consisting of aluminum nitride ceramics, silicon nitride ceramics, and aluminum oxide ceramics.

3. The metal-ceramic substrate according to claim 1, wherein the metal layer comprises copper.

4. The metal-ceramic substrate according to claim 1, wherein the solid material contains metal of the metal layer.

5. The metal-ceramic substrate according to claim 1, wherein the non-solid material contains gaseous material.

6. The metal-ceramic substrate according to claim 1, wherein the following requirement is met:
$$A ( {BCD}_{solid} ) / A ( {BCD}_{total} ) > 95 \% .$$

7. The metal-ceramic substrate according to claim 1, wherein the sample standard deviation SSD of the ratio A (BCD_{solid})/A (BCDₜₒₜₐₗ) over at least ten different cross sections of the structuring region of the metal layer is not more than 10%.

8. An electronic component comprising a metal-ceramic substrate according to claim 1.
